(19) United States
(12) Patent Application Publication
(10) Pub. No.: US 2014/0182822 A1
(43) Pub. Date: Jul. 3, 2014

(54) HEAT DISSIPATION MODULE

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: XIANG-KUN ZENG, Shenzhen (CN); BAO-QUAN SHI, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 14/016,228

(22) Filed: Sep. 3, 2013

(30) Foreign Application Priority Data
Dec. 28, 2012 (CN) 2012105825887

(51) Int. Cl. H05K 7/20

(52) U.S. Cl. CPC H05K 7/20409
USPC 165/122

(57) ABSTRACT

A heat dissipation module includes an encasing structure, a fan impeller mounted in the encasing structure, a heat dissipation piece, and a bearing. The fan impeller includes a mounting post and a plurality of fan blades surrounding the post. The heat dissipation piece is mounted in a base plate of the encasing structure and configured for directly contacting with a heat generating component. The bearing is mounted on the heat dissipation piece. The mounting post is pivotably mounted in the bearing. The fan impeller is capable of dissipating heat generated by the heat generating component when the mounting post is rotating in the bearing.

### BACKGROUND

1. Technical Field

The present disclosure relates to a heat dissipation module.

2. Description of Related Art

A computer includes a plurality of heat generating components which generate heat during operation. A heat dissipation module is utilized to dissipate heat generated by the plurality of heat generating components to the outside of the computer. The heat dissipation module includes a heat sink apparatus and a fan mounted on the heat sink apparatus. The heat dissipation module should possess good heat dissipation ability. However, the heat dissipation module occupies much space which is not suitable in a small-sized computer, such as a notebook computer or a tablet.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of an embodiment of a heat dissipation module.

FIG. 2 is similar to FIG. 1, but viewed from another aspect.

FIG. 3 is an assembled view of the heat dissipation module of FIG. 1.

### DETAILED DESCRIPTION

The disclosure is illustrated by way of example and not by way of limitation. In the figures of the accompanying drawings in which like references indicate similar elements. It should be noted that references to “an” or “one” embodiment in this disclosure are not necessarily to the same embodiment, and such references mean “at least one.”

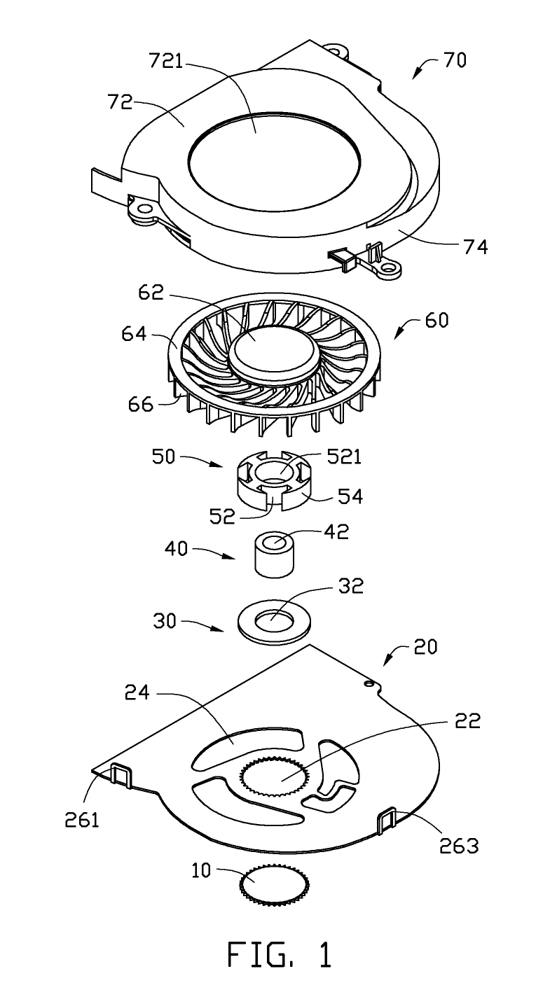

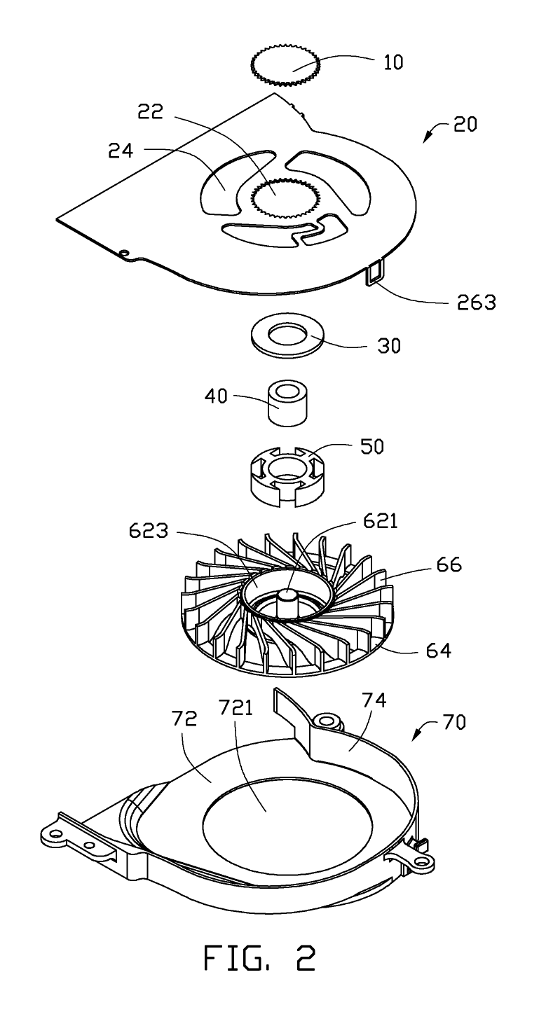

FIGS. 1 and 2 show an embodiment of a heat dissipation module. The heat dissipation module includes a heat dissipation piece 10, a base plate 20, a circuit board 30, a bearing 40, a mounting member 50, a fan impeller 60, and a housing 70.

The heat dissipation piece 10 has a circular, serrated shape. The heat dissipation piece 10 is made from metal material having good heat transfer ability. The heat dissipation piece 10 can directly touch a heat generating component for dissipating heat generated by the heat generating component.

A mounting opening 22 is defined in the base plate 20 for mounting the heat dissipation piece 10. A plurality of ventilation openings 24 is defined in the base plate 20 and surrounds the mounting opening 22. A first blocking piece 261 and a second blocking piece 263 protrude from an edge of the base plate 20. Both the first blocking piece 261 and the second blocking piece 263 have an inverted U shape and are substantially perpendicular to the base plate 20.

The circuit board 30 can have a ring shape. A mounting hole 32 is defined in a central portion of the circuit board 30. An outer diameter of the circuit board 30 is greater than the diameter of the mounting opening 22.

The bearing 40 has a hollow, cylindrical shape. A first mounting groove 42 is defined in the bearing 40 along an axial direction of the bearing 40. An outer diameter of the bearing 40 is not greater than the diameter of the mounting hole 32. Thus, the bearing 40 can be mounted in the mounting hole 32.

The mounting member 50 includes a central cylindrical portion 52, and a plurality of mounting blocks 54 extending from a peripheral wall of the central cylindrical portion 52 along a direction that is substantially perpendicular to an axis of the mounting member 50. Each of the plurality of mounting blocks 54 has a T-shape or a mushroom shape. A second mounting groove 521 is defined in the central cylindrical portion 52. A diameter of the second mounting groove 521 is not less than the outer diameter of the bearing 40. Thus, the bearing 40 can be received in the second mounting groove 521.

The fan impeller 60 includes a central circular plate 62, a ring-shaped outer flange 64, and a plurality of fan blades 66 connected to the central circular plate 62 and the ring-shaped outer flange 64. The central circular plate 62 and the ring-shaped outer flange 64 are located at an upper side of the fan impeller 60. A circular peripheral wall 623 extends inwardly from a peripheral edge of the central circular plate 62. The plurality of fan blades 66 extends from the circular peripheral wall 623 regularly. A first end of each of the plurality of fan blades 66 is connected to the circular peripheral wall 623. A second end of each of the plurality of fan blades 66 is connected to the ring-shaped outer flange 64. Each of the plurality of fan blades 66 is substantially perpendicular to the central circular plate 62 and the ring-shaped outer flange 64. A mounting post 621 extends inwardly from a central portion of the central circular plate 62. A height of the mounting post 621 is substantially equal to that of the circular peripheral wall 623. A width of each of the plurality of fan blades 66 is substantially equal to the height of the circular peripheral wall 623. A diameter of the circular peripheral wall 623 is not less than a maximum diameter of the mounting member 50. A diameter of the mounting post 621 is not greater than the diameter of the first mounting groove 42. The mounting post 621 can be pivotably mounted in the first mounting groove 42.

The housing 70 includes a main plate 72 and a side flange 74 extending substantially perpendicularly from an outer edge of the main plate 72. An airflow outlet 721 is defined in the main plate 72. A diameter of the airflow outlet 721 is substantially equal to an inner diameter of the ring-shaped outer flange 64. A shape and size of the main plate 72 is substantially the same as that of the base plate 20.

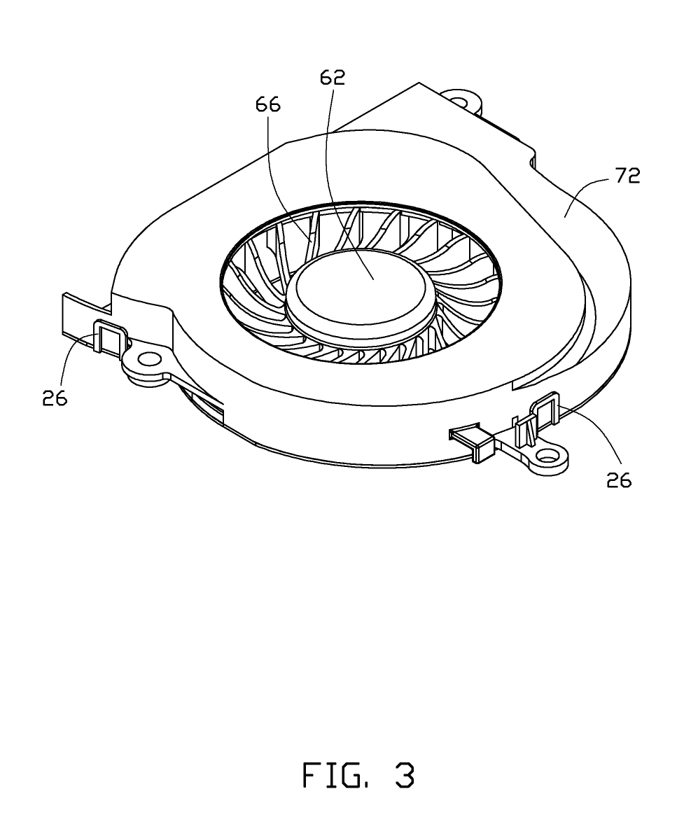

FIGS. 1 to 3 show in assembly, the bearing 40 is secured on the heat dissipation piece 10. The heat dissipation piece 10 is mounted in the mounting opening 22. The bearing 40 extends through the mounting hole 32. The circuit board 30 is mounted on the heat dissipation piece 10. The second mounting groove 521 is aligned with a top surface of the bearing 40. The bearing 40 extends through the second mounting groove 521. A bottom of the mounting member 50 lies on the circuit board 30. The mounting member 50 is encased by the circular peripheral wall 623. The bearing 40 is received in the second mounting groove 521. The mounting post 621 is received in the first mounting groove 42. The side flange 74 is secured to the outer edge of the base plate 20. The first blocking piece 261 and the second blocking piece 263 abuts the side flange 74. The housing 70 is secured to the base plate 20. The fan impeller 60 is encased by and located between the housing 70 and the base plate 20. In one embodiment, a thickness of the fan impeller 60 along an axial direction of the fan impeller 60 is less than a width of the side flange 74. Thus, the fan impeller 60 is rotatable in a space between the housing 70 and the base plate 20.

In one embodiment, the circuit board 30 is used to control a rotating speed of the fan impeller 60. The mounting member 50 is a part of an electronic component which includes a coil of wire wrapped around the plurality of mounting blocks 54. Each of the housing 70, the base plate 20, the bearing 40, the mounting member 50, and the fan impeller 60 is made from metal material having good heat transfer ability. When the heat dissipation module is operating, the heat dissipation piece 10 contacts the heat generating component. Heat generated by the heat generated component is transferred to the heat dissipation piece 10, the bearing 40, and the fan impeller 60. The plurality of fan blades 66 rotate, thereby removing heat via the airflow outlet 721.

While the present disclosure has been illustrated by the description of preferred embodiments thereof, and while the preferred embodiments have been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A heat dissipation module comprising:
a base plate;
a housing attached to the base plate;
a fan impeller located between the housing and the base plate, and comprising a mounting post and a plurality of fan blades surrounding the post;
a heat dissipation piece mounted in the base plate and configured for directly contacting a heat generating component;
a bearing mounted on the heat dissipation piece;
wherein the mounting post is pivotably mounted in the bearing; and the fan impeller is capable of dissipating heat generated by the heat generating component when the mounting post is rotating in the bearing.

2. The heat dissipation module of claim 1, wherein a mounting opening is defined in the base plate for mounting the heat dissipation piece, and a plurality of ventilation openings is defined in the base plate and surrounds the mounting opening.

3. The heat dissipation module of claim 1, wherein the housing comprises a main plate and a side flange extending substantially perpendicularly from an edge of the main plate, and an airflow outlet is defined in the main plate.

4. The heat dissipation module of claim 3, wherein a shape and size of the main plate is substantially the same as that of the base plate, the side flange is attached to an outer edge of the base plate, and a width of the side flange is greater than a thickness of the fan impeller along an axis direction of the fan impeller.

5. The heat dissipation module of claim 1, further comprising a ring-shaped circuit board configured to control a rotating speed of the fan impeller, wherein the bearing extends through the ring-shaped circuit board.

6. The heat dissipation module of claim 5, further comprising a mounting member attached to the fan impeller, wherein a first mounting groove is defined in the bearing, and a second mounting groove is defined in the mounting member for receiving the bearing.

7. The heat dissipation module of claim 6, wherein the fan impeller comprises a central circular plate and a ring-shaped outer flange, the plurality of fan blades is connected to the central circular plate and the ring-shaped outer flange, and the mounting post extends from the central circular board and is pivotably mounted in the first mounting groove.

8. The heat dissipation module of claim 7, wherein the central circular plate and the ring-shaped outer flange are located an upper side of the fan impeller, a circular peripheral wall extends substantially perpendicularly and downwardly from a peripheral edge of the central circular plate; and the plurality of fan blades extends from the circular peripheral wall regularly to the ring-shaped outer flange.

9. The heat dissipation module of claim 8, wherein each of the plurality of fan blades is substantially perpendicular to the central circular plate and the ring-shaped outer flange.

10. The heat dissipation module of claim 6, wherein each of the heat dissipation piece, the base plate, the bearing, the mounting member, the fan impeller, and the housing is made from metal material.

11. A heat dissipation module comprising:
a base plate with a mounting opening;
a housing attached to the base plate;
a fan impeller mounted between the housing and the base plate, and comprising a mounting post and a plurality of fan blades surrounding the post;
a heat dissipation piece mounted in the mounting opening and configured for directly contacting a heat generating component;
a bearing mounted on the heat dissipation piece, wherein a first mounting groove is defined in the bearing; the mounting post is pivotably mounted in the first mounting groove; and the fan impeller dissipates heat generated by the heat generating component when the mounting post is rotating in the first mounting groove.

12. The heat dissipation module of claim 11, wherein the housing comprises a main plate and a side flange extending substantially perpendicularly from an edge of the main plate, and an airflow outlet defined in the main plate.

13. The heat dissipation module of claim 12, wherein a shape and size of the main plate is substantially the same as that of the base plate, the side flange is attached to an outer edge of the base plate, and a width of the side flange is greater than a thickness of the fan impeller along an axis direction of the fan impeller.

14. The heat dissipation module of claim 11, further comprising a ring-shaped circuit board configured to control a rotating speed of the fan impeller, wherein the bearing extends through the ring-shaped circuit board and is secured on the heat dissipation piece.

15. The heat dissipation module of claim 14, further comprising a mounting member attached to the fan impeller, wherein a second mounting groove is defined in the mounting member for receiving the bearing.

16. The heat dissipation module of claim 15, wherein the fan impeller comprises a central circular plate and a ring-shaped outer flange, the plurality of fan blades is connected to the central circular plate and the ring-shaped outer flange, and the mounting post extends from the central circular board.

17. The heat dissipation module of claim 16, wherein the central circular plate and the ring-shaped outer flange are located at an upper side of the fan impeller, a circular peripheral wall extends substantially perpendicularly and downwardly from a peripheral edge of the central circular plate; and the plurality of fan blades extends from the circular peripheral wall regularly to the ring-shaped outer flange.

18. The heat dissipation module of claim 17, wherein each of the plurality of fan blades is substantially perpendicular to the central circular plate and the ring-shaped outer flange.

19. The heat dissipation module of claim 18, wherein a diameter of the airflow outlet is substantially equal to an inner diameter of the ring-shaped outer flange for exposing the fan blades.

20. The heat dissipation module of claim 15, wherein each of the heat dissipation piece, the base plate, the bearing, the mounting member, the fan impeller, and the housing is made from metal material.
